(19) United States
(12) Patent Application Publication
(10) Pub. No.: US 2025/0273262 A1
(43) Pub. Date: Aug. 28, 2025

(54) 2T DRAM CELL WITH ASYMMETRIC PARASITIC CAPACITOR AND 2T DRAM CELL ARRAY

(71) Applicant: POSTECH RESEARCH AND BUSINESS DEVELOPMENT FOUNDATION, Pohang-si (KR)

(72) Inventors: Yoonyoung CHUNG, Pohang-si (KR); Suwon SEONG, Pohang-si (KR); Daehwan KANG, Pohang-si (KR); Sung Woong CHUNG, Pohang-si (KR)

(21) Appl. No.: 19/059,977

(22) Filed: Feb. 21, 2025

(30) Foreign Application Priority Data
Feb. 23, 2024 (KR) 10-2024-0026247
Jan. 20, 2025 (KR) 10-2025-0007741

(51) Int. Cl. G11C 11/4096; G11C 5/06

(52) U.S. Cl. CPC G11C 11/4096; G11C 5/063

(57) ABSTRACT

The present disclosure provides a 2T DRAM cell with an asymmetric parasitic capacitor capable of blocking a flow of current that may occur in an unselected 2T DRAM cell during a read operation of a selected 2T DRAM cell by adding the asymmetric parasitic capacitor to a read transistor constituting the 2T DRAM cell, and a 2T DRAM cell array. The 2T DRAM cell with an asymmetric parasitic capacitor includes a write transistor, a read transistor, and an asymmetric parasitic capacitor formed between the gate terminal of the read transistor and the other terminal of the read transistor connected to the read word line.

This application claims priority from and the benefit of Korean Patent Application No. 10-2024-0026247, filed on Feb. 23, 2024, and Korean Patent Application No. 10-2025-0007741, filed on Jan. 20, 2025, and which is hereby incorporated by reference for all purposes as if set forth herein.

### BACKGROUND

### 1. Field

The present disclosure relates to a 2-transistor DRAM (2T DRAM) cell composed of two transistors, and more particularly, to a 2T DRAM cell with an asymmetric parasitic capacitor capable of blocking a flow of current that may occur in an unselected 2T DRAM cell during a read operation of a selected 2T DRAM cell by adding the asymmetric parasitic capacitor to a read transistor constituting the 2T DRAM cell, and a 2T DRAM cell array.

### 2. Description of Related Art

The existing DRAM with a 1T1C cell structure composed of one access transistor and one capacitor has been widely used as a main memory of a current computer due to its advantages of fast operation speed and high integration. However, as the miniaturization of DRAM cells continues, the leakage level of the charge stored in the DRAM cell is increasing, and the manufacturing difficulty of capacitors with high density and capacity is also rapidly increasing, making the miniaturization process difficult.

Recently, in order to overcome the limitations of the 1T1C DRAM, a 2T0C DRAM without a capacitor using oxide semiconductor transistors such as InGaZno (IGZO), which are widely used in the display industry, is attracting attention. A band gap voltage of IGZO (3.2 eV) is about three times larger than that (1.12 eV) of Si, which shows very large asymmetric mobility between electrons and holes, resulting in very low leakage current. Accordingly, it is possible to maintain a storage state of charge corresponding to information for a certain period of time even in a 2T0C (hereinafter referred to as 2T) DRAM structure without a capacitor. It has also been widely known that IGZO 2T DRAM has a data retention time of at least several hours.

FIGS. 1A and 1B illustrate a circuit and operating characteristics of the conventional 2T DRAM cell.

Referring to the circuit of the 2T DRAM cell illustrated in FIG. 1A, it can be seen that the 2T DRAM cell includes one write transistor WT and one read transistor RT.

A write operation for storing information in the 2T DRAM cell is performed by charging or discharging a charge corresponding to information stored in a write bit line WBL applied to the 2T DRAM cell through a write transistor WT that is activated according to a voltage level of a write word line WWL, to or from a storage node SN which is a gate terminal of a read transistor RT. In the following description, the charge charged to the storage node SN and a storage node voltage VSN of the storage node SN of the 2T DRAM cell will be used as the same meaning.

During a read operation, the read transistor RT is turned on or off according to the level of the storage node voltage VSN stored in the storage node SN after the write operation.

One terminal of the read transistor RT included in the 2T DRAM cell is connected to a read bit line RBL and the other terminal is connected to a read word line RWL. A ground voltage GND is applied to the other terminal of the read transistor RT of the 2T DRAM cell selected to perform the read operation through the read word line RWL. Accordingly, the voltage level of the read bit line RBL may change by the amount of current flowing from the read bit line RBL toward the read word line RWL through the selected read transistor RT, and the degree of change in the voltage VRBL of the read bit line RBL may be sensed by a sensor unit (not illustrated) to determine the information stored in the 2T DRAM cell.

In the following description, when “H” information is stored in the storage node SN, the corresponding read transistor RT is turned on during the read operation, so a current flows smoothly from the read bit line RBL toward the read word line RWL, and when “L” information is stored in the storage node SN, the corresponding read transistor RT is turned off during the read operation, so a current does not flow from the read bit line RBL toward the read word line RWL. For example, when expressed in a binary number, “H” corresponds to “1 (one)”, and “L” corresponds to “0 (zero)”.

FIG. 1B illustrates the flow of current during the read operation of the 2T DRAM cell array.

For convenience of description, FIG. 1B selectively illustrates two 2T DRAM cells in the 2T DRAM cell array, where the upper 2T DRAM cell is a cell selected to perform the read operation, and the lower 2T DRAM cell is a cell that is not selected as a cell performing the read operation.

Referring to FIG. 1B, when the read current is applied from the selected 2T DRAM cell (upper portion) to the read bit line RWL connected to a ground voltage GND during the read operation, it can be seen that an undesired current flow from the read bit line RWL connected to a first voltage VDD in an unselected 2T DRAM cell (lower portion) toward the read bit line RWL.

In order to read the information stored in the selected 2T DRAM cell (hereinafter referred to as DRAM cell) while the read bit line RBL is pre-charged with the first voltage VDD, when the ground voltage GND is applied only to the read word line RWL of the selected DRAM cell (upper cell) and the first voltage VDD is applied to the read word line RWL of the unselected DRAM cell (lower cell), a read current (arrow) flows from the read bit line RBL toward the read word line RWL according to the information stored in the selected DRAM cell, so the voltage level of the read bit line RBL changes. Here, the first voltage VDD means a voltage source having a relatively higher voltage level than the ground voltage GND.

Referring to FIG. 1B, when the selected DRAM cell stores ‘H’, the voltage level VRBL of the read bit line RBL decreases due to the read current (arrow), and the decreased voltage level VRBL is sensed to determine that the information stored in the selected cell is “H”.

While reading the information in the selected DRAM cell, the voltage level of the read bit line RBL decreases to VDD−VTH. Here, VTH is a threshold voltage of the read transistor RT. In this case, when ‘H’ is stored in the unselected DRAM cell, the read transistor RT of the unselected cell is activated and connected to another terminal of the corresponding read transistor RT, and an undesired current (arrow) flows from the read word line RWL having the voltage level of the first voltage VDD toward the read bit line RBL. This current (arrow) unintentionally changes the voltage level VRBL of the read bit line RBL, so an error in the read operation occurs.

In order to prevent the undesired current in the 2T DRAM cell array, a method for blocking a flow of undesired current from unselected cells is required.

FIGS. 2A and 2B illustrate a circuit of a conventional cell that blocks the flow of undesired current that may occur in unselected cells during a read operation.

FIG. 2A illustrates an example of a circuit that adds a gate terminal to always turn off the unselected read transistor during the read operation, and FIG. 2B illustrates an example of a 3T0C DRAM cell in which an additional transistor T2 is included in a cell.

However, the proposed circuit illustrated in FIGS. 2A and 2B have the disadvantage of making the manufacturing process more complicated and making it difficult to miniaturize the DRAM cell array due to the added gate terminal.

### SUMMARY

The present disclosure provides a 2T DRAM cell with an asymmetric parasitic capacitor capable of blocking a flow of current that may occur in an unselected 2T DRAM cell during a read operation of a selected 2T DRAM cell by adding the asymmetric parasitic capacitor to a read transistor constituting a 2T DRAM cell.

In addition, the present disclosure provides a 2T DRAM cell array including a 2T DRAM cell with an asymmetric parasitic capacitor capable of blocking a flow of current that may occur in an unselected 2T DRAM cell during a read operation of a selected 2T DRAM cell by adding the asymmetric parasitic capacitor to a read transistor constituting a 2T DRAM cell.

Objects of the present disclosure are not limited to the above-mentioned objects. That is, other objects that are not mentioned may be obviously understood by those skilled in the art to which the present disclosure pertains from the following description.

According to an embodiment of the present disclosure, a 2T DRAM cell with an asymmetric parasitic capacitor includes a write transistor having one terminal connected to a write bit line, the other terminal connected to a storage node, and a gate terminal connected to a write word line, a read transistor having one terminal connected to a read bit line, the other terminal connected to a read word line, and a gate terminal connected to the storage node, and an asymmetric parasitic capacitor formed between the gate terminal of the read transistor and the other terminal of the read transistor connected to the read word line.

According to another embodiment of the present disclosure, a 2T DRAM cell array includes the plurality of 2T DRAM cells described above, each of which is connected to a write word line, a write bit line, a read word line, and a read bit line, wherein when a read operation is performed on information stored in a selected 2T DRAM cell among the plurality of 2T DRAM cells, a read transistor of an unselected 2T DRAM cell among the plurality of 2T DRAM cells is always turned off by the asymmetric parasitic capacitor included in the 2T DRAM cell.

Objects of the present disclosure are not limited to the above-described objects, and other objects that are not mentioned may be obviously understood by those having ordinary skill in the art to which the present disclosure pertains from the following description.

### BRIEF DESCRIPTION OF DRAWINGS

FIGS. 1A and 1B illustrate a circuit and operating characteristics of the conventional 2T DRAM cell.

FIGS. 2A and 2B illustrate a circuit of a conventional cell that blocks the flow of undesired current that may occur in unselected cells during a read operation.

FIG. 3 is a diagram illustrating an embodiment of a circuit of a 2T DRAM cell with an asymmetric parasitic capacitor according to the present disclosure.

FIG. 4 is a diagram illustrating changes in a read word line and a storage node voltage due to the asymmetric parasitic capacitor.

FIG. 5 is a diagram illustrating a mathematical formula including a process of calculating a change in a voltage level of a storage node of an unselected DRAM cell during a read operation.

FIG. 6 is a diagram illustrating a method of driving a 2T DRAM cell with an asymmetric parasitic capacitor according to the present disclosure.

FIGS. 7A and 7B are a diagram illustrating a specific embodiment of the method of driving a 2T DRAM cell with an asymmetric parasitic capacitor according to the present disclosure.

FIGS. 8A and 8B are a diagram illustrating voltage levels of each node during a read operation of a selected DRAM cell.

FIGS. 9A to 9D illustrate an embodiment of a cross-sectional structures of a 2T DRAM cell with an asymmetric parasitic capacitor according to the present disclosure.

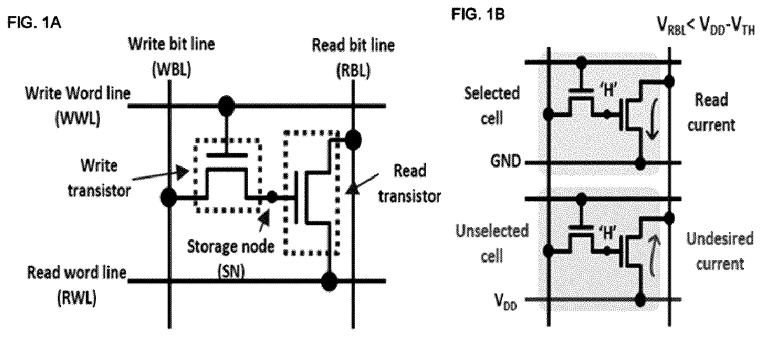

### DETAILED DESCRIPTION

In order to sufficiently understand the present disclosure, operational advantages of the present disclosure, and objects accomplished by embodiments of the present disclosure, the accompanying drawings for describing exemplary embodiments of the present disclosure and contents described in the accompanying drawings should be referred to.

Hereinafter, exemplary embodiments of the present disclosure will be described in detail with reference to the accompanying drawings. The same reference numerals in each drawing denote the same components.

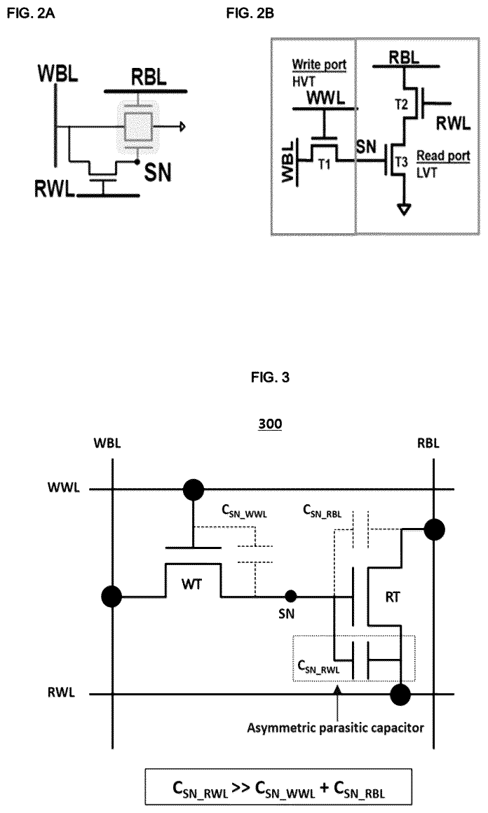

FIG. 3 is a diagram illustrating an embodiment of a circuit of a 2T DRAM cell with an asymmetric parasitic capacitor according to the present disclosure.

Referring to FIG. 3, a 2T DRAM cell 300 with an asymmetric parasitic capacitor according to the present disclosure includes a write transistor WT and a read transistor RT.

The write transistor WT has one terminal connected to a write bit line WBL, the other terminal connected to a storage node SN, and a gate terminal connected to a write word line WWL. The read transistor RT has one terminal connected to a read bit line RBL, the other terminal connected to a read word line RWL, and a gate terminal connected to the storage node SN.

Referring to FIG. 3, it can be seen that a first parasitic capacitor C_{SN_WWL} exists between the gate terminal of the write transistor WT and another terminal SN, and a second parasitic capacitor C_{SN_RBL} exists between the gate terminal SN and one terminal RBL of the read transistor RT.

The first parasitic capacitor C_{SN_WWL} and the second parasitic capacitor C_{SN_RBL} are indicated by dotted lines to emphasize that they are unintentionally generated due to an overlapping or adjacent portion of a mask pattern of the gate terminals of the transistors WT and RT with a drain terminal or a source terminal, which is an active area of the transistor, during manufacturing of the transistor. The expression “unintentional” here reflects that a gate pattern is generated larger than an area that actually becomes the channel by considering the misalignment of the mask and the wafer during the semiconductor manufacturing process.

A third parasitic capacitor C_{SN_RWL} proposed in the present disclosure is generated between the gate terminal SN of the read transistor RT and the other terminal RWL, which is an active area of the read transistor RT electrically connected to the read word line RWL. The third parasitic capacitor C_{SN_RWL} is not generated unintentionally during the manufacturing process of the transistor, but is indicated by a solid line in that the third parasitic capacitor C_{SN_RWL} is a capacitor that is generated by intentionally extending the mask pattern corresponding to the gate terminal to the other terminal of the read transistor RT, that is, the source or drain area and using the mask.

There are various methods of manufacturing the third parasitic capacitor C_{SN_RWL}, which is the asymmetric parasitic capacitor. For example, the area of the overlapping portion between the gate terminal of the read transistor RT and the source or drain terminal of the read transistor RT connected to the read word line RWL is made larger than the area of the overlapping portion between the gate terminal of the read transistor RT and the source or drain terminal connected to the read bit line RBL. That is, the area of the pattern of the gate terminal of the portion that becomes the third parasitic capacitor C_{SN_RWL} is defined to be larger than the area considering the misalignment of the mask and the wafer, but it is intentionally overlapped.

Alternatively, the third parasitic capacitor C_{SN_RWL}, which is the asymmetric parasitic capacitor, may be implemented by adding a pattern corresponding to the third parasitic capacitor C_{SN_RWL}, which is the asymmetric parasitic capacitor, to the mask defining the gate terminal.

When writing to be larger than the area considering the misalignment of the mask and the wafer, the capacitance of the third parasitic capacitor C_{SN_RWL} should be sufficiently larger than the sum of the capacitance of the first parasitic capacitor C_{SN_WWL} and the capacitance of the second parasitic capacitor C_{SN_RBL}, as illustrated at the bottom of FIG. 3, for the size of the additionally extended gate pattern.

Here, the meaning of being sufficiently large is that the capacitance of the third parasitic capacitor C_{SN_RWL} should be such that the sum of the capacitance of the first parasitic capacitor C_{SN_WWL} and the capacitance of the second parasitic capacitor C_{SN_RBL} may be mathematically ignored, and the reason for this will be described later.

The expression that the third parasitic capacitor C_{SN_RWL} is the asymmetrical parasitic capacitor reflects that the second parasitic capacitor C_{SN_RBL} generated between the gate terminal SN and the terminal RBL terminal of the same read transistor RT is a parasitic capacitor symmetrical to the third parasitic capacitor C_{SN_RWL}, but the capacitance of the third parasitic capacitor C_{SN_RWL} is so large that it may not be compared with the capacitance of the second parasitic capacitor C_{SN_RBL}.

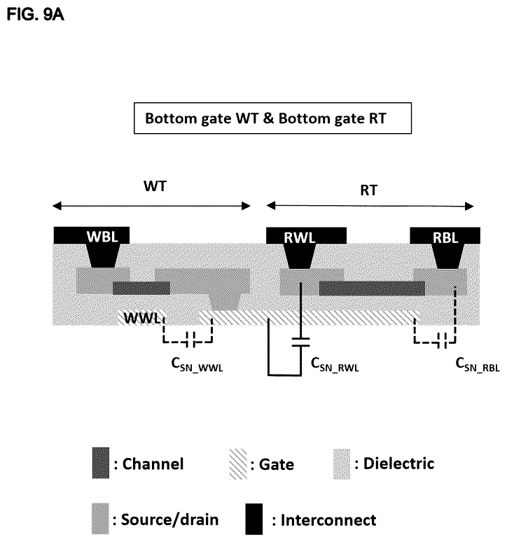

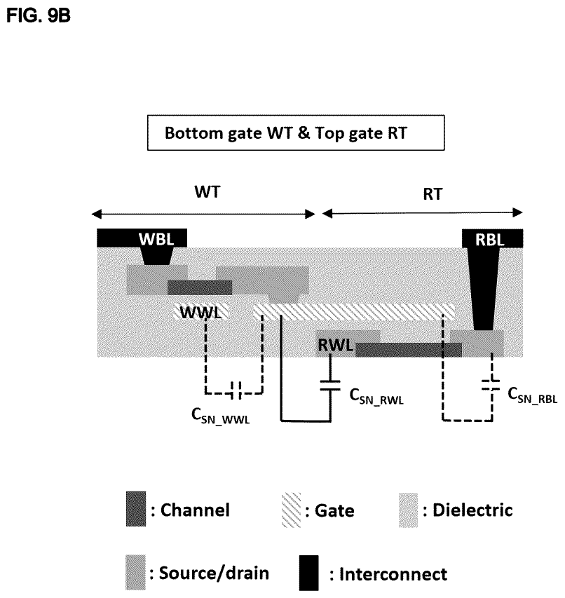

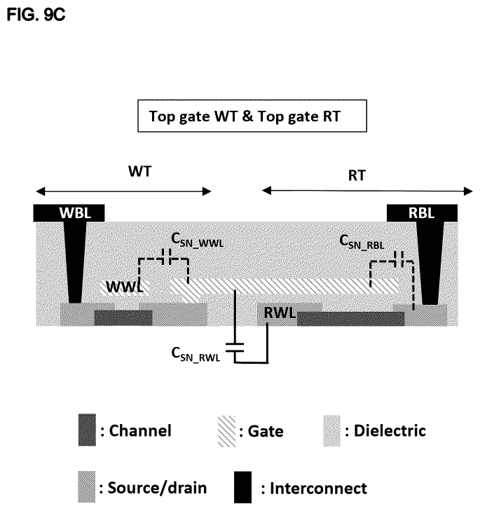

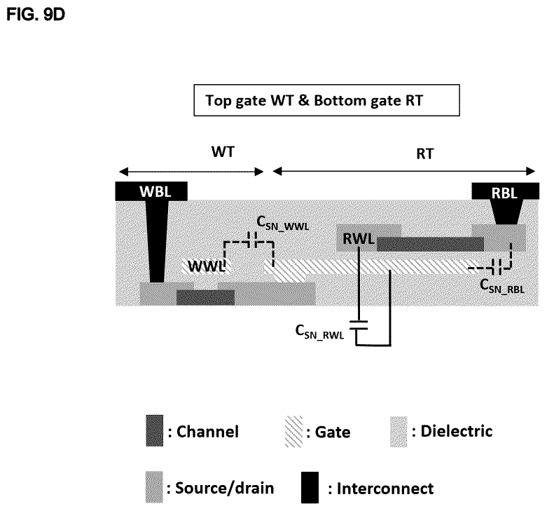

Referring to FIG. 9A to FIG. 9D, it can be seen that a first parasitic capacitor C_{SN_WWL} exists between the gate terminal of the write transistor WT and another terminal SN, and a second parasitic capacitor C_{SN_RBL} exists between the gate terminal SN and one terminal RBL of the read transistor RT. The third parasitic capacitor C_{SN_RWL} is formed between one terminal RWL in the active region of the read transistor RT, which is electrically connected to the storage node (SN) and the read word line RWL. Therefore, the third parasitic capacitor C_{SN_RWL} is intentionally formed with a capacitance value proportional to the area where the active region overlaps with the gate terminal SN.

For reference, FIG. 9A shows that the gates of the write transistor WT and the read transistor RT are both formed below their respective channels. FIG. 9B shows that the gate of the write transistor WT is formed below the channel, while the gate of the read transistor RT is formed above the channel. FIG. 9C shows that the gates of the write transistor WT and the read transistor RT are both formed above their respective channels. FIG. 9D shows that the gate of the write transistor WT is formed above the channel, while the gate of the read transistor RT is formed below the channel.

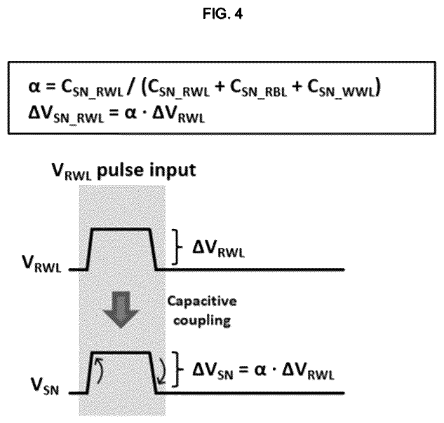

FIG. 4 is a diagram illustrating the changes in the read word line and the storage node voltage due to the asymmetric parasitic capacitor.

Voltage levels of a read word line voltage V_{RWL} and a storage node voltage V_{SN} illustrated in FIG. 4 may be obtained through the following computational process.

Hereinafter, first, the change in the storage node voltage V_{SN} due to capacitive coupling in the read transistor RT with the third parasitic capacitor C_{SN_RWL}, which is the asymmetric parasitic capacitor, will be described with reference to the circuit illustrated in FIG. 3.

After the write operation is completed, when the write transistor WT is turned off, the charge stored in the storage node SN is blocked from moving and is in a floating state, and the charge QSN stored in the storage node SN satisfies the condition f the following Mathematical Formula 1. In this case, it is assumed that the read transistor RT is maintained in the turned-off state, and the effect of a gate oxide film Cox of the read transistor RT is ignored when considering the charge stored in the storage node SN.

Q_{SN}=(V_{SN}−V_{RWL})·C_{SN_RWL}+(V_{SN}−V_{RBL})·C_{SN_RBL}+(V_{SN}−V_{WWL})·C_{SN_WWL} [Mathematical Formula 1]

V_{SN} denotes the voltage level of the storage node, V_{RWL} denotes the voltage level of the read word line RWL, V_{RBL} denotes the voltage level of the read bit line RBL, and V_{WWL} denotes the voltage level of the write word line WWL, respectively.

In this case, for the read operation, when it is assumed that a voltage pulse of AVRWL is applied to the read word line RWL while the voltage applied to the write word line WWL and the read bit line RBL is maintained as it is, the charge Q's stored in the storage node SN at this time may be expressed as in the following Mathematical Formula 2.

Q′_{SN}=(V′_{SN}−(V_{RWL}+ΔV_{RWL}))·C_{SN_RWL}+(V′_{SN}−V_{RBL})·C_{SN_RBL}+(V′_{SN}−V_{WWL})·C_{SN_WWL} [Mathematical Formula 2]

In order to obtain the voltage change amount of the storage node voltage V_{SN} before (Mathematical Formula 1) and after (Mathematical Formula 2) applying the voltage pulse of ΔV_{RWL} to the read word line RWL, the above Mathematical Formula 2 may be subtracted from the above Mathematical Formula 1 to obtain the following Mathematical Formula 3.

$${Q}_{SN} - {Q}_{SN}^{′} = ( ( {V}_{SN} - {V}_{SN}^{′} ) - Δ {V}_{RWL} ) \cdot {C}_{SN \_ RWL} + ( {V}_{SN} - {V}_{SN}^{′} ) \cdot {C}_{SN \_ RBL} + ( {V}_{SN} - {V}_{SN}^{′} ) \cdot {C}_{SN \_ WWL} \qquad [ Mathematical Formula 3 ]$$

Since the law of conservation of charge is applied to the storage node SN, it will be Q_{SN}−Q′_{SN}=0. When the voltage change amount of the storage node voltage V_{SN} is ΔV_{SN}, if it is assumed that ΔV_{SN}=V_{SN}−V′_{SN}, the above Mathematical Formula 3 may be organized as described in the following Mathematical Formula 4.

$$( Δ {V}_{SN} - Δ {V}_{RWL} ) \cdot {C}_{SN \_ RWL} + Δ {V}_{SN} \cdot {C}_{SN \_ RBL} + Δ {V}_{SN} \cdot {C}_{SN \_ WWL} = 0 \qquad [ Mathematical Formula 4 ]$$

$$( \frac{Δ {V}_{SN}}{Δ {V}_{R W L}} - 1 ) \cdot {C}_{SN \_ RWL} + \frac{Δ {V}_{SN}}{Δ {V}_{RWL}} \cdot {C}_{SN \_ RBL} + \frac{Δ {V}_{SN}}{Δ {V}_{RWL}} \cdot {C}_{SN \_ WWL} = 0$$

$$\frac{Δ {V}_{SN}}{Δ {V}_{RWL}} ( {C}_{SN \_ RWL} + {C}_{SN \_ RBL} + {C}_{SN \_ WWL} ) - {C}_{SN \_ WWL} = 0$$

$$Δ {V}_{SN} = \frac{{C}_{SN \_ RWL}}{( {C}_{SN \_ RWL} + {C}_{SN \_ RBL} + {C}_{SN \_ WWL} )} \cdot Δ {V}_{RWL} = ∝ \cdot Δ {V}_{RWL} {C}_{SN \_ RWL} ≫ {C}_{SN \_ RBL} + {C}_{SN \_ WWL} ∝ = 1$$

As described in the lower portion of FIG. 3, the relationship between three parasitic capacitors may be expressed as

C_{SN_RWL}>>C_{SN_RBL}+C_{SN_WWL},

so the final relationship of the above Mathematical Formula 4 will be satisfied.

The mathematical condition for a to be 1 in the above Mathematical Formula 4 may be, for example, that the magnitude of the capacitance of the asymmetric parasitic capacitor C_{SN_RWL} is at least 1000 times larger than the magnitude of the sum of the capacitance of the first parasitic capacitor C_{SN_WWL} formed between the gate terminal of the write transistor WT and the storage node SN and the capacitance of the second parasitic capacitor C_{SN_RWL} formed between the gate terminal of the read transistor RT and the storage node SN.

That is, since the voltage level of the storage node SN also changes at the same rate as the voltage level of the read word line RWL, the threshold voltage of the read transistor RT does not change, so even if the voltage level of the read word line RWL of the DRAM cell that is not selected for the read operation changes, the read transistor RT included in the unselected DRAM cell will not be turned on.

The voltage of the read bit line RBL will change due to the read current flowing in the DRAM cell selected in the read operation. In this case, the change in the voltage level of the storage node SN of the unselected DRAM cell will be described.

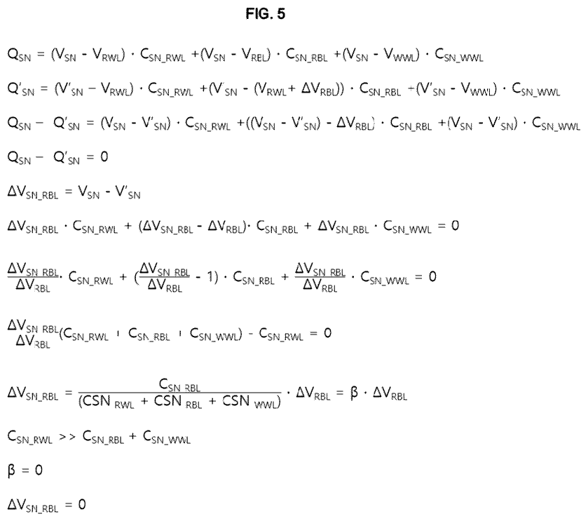

FIG. 5 is a diagram illustrating a mathematical formula including a process of calculating a change in a voltage level of a storage node of an unselected DRAM cell during a read operation.

In FIG. 5, the mathematical formula and its

organizing process may be applied to the mathematical formulae shown in the above Mathematical Formulae 1 to 4 as it is, so a description thereof will be omitted herein.

Referring to the final mathematical formula ΔV_{SN_RBL}=0 illustrated in FIG. 5, it can be seen that the voltage of the read bit line RBL does not change regardless of the voltage level of the storage node SN of the unselected DRAM cell.

That is, it can be seen that the change in the read word line RWL supplied to the unselected DRAM cell during the read operation and the voltage change in the read bit line RBL due to the read current of the selected DRAM cell do not affect the turn-on of the read transistor RT of the unselected DRAM cell at all. That is, it can be seen that the read transistor RT of the unselected DRAM cell maintains the turn-off state as it is in the read mode in which the other cell is selected by the capacitance by the third parasitic capacitor C_{SN_RWL}.

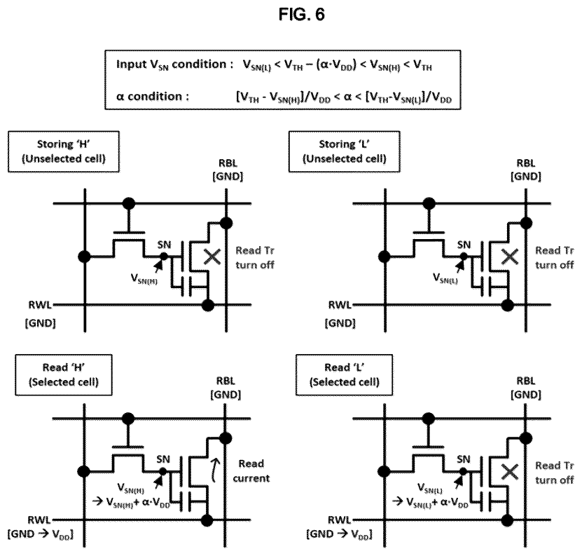

FIG. 6 is a diagram illustrating a method of driving a 2T DRAM cell with asymmetric parasitic capacitance according to the present disclosure.

FIG. 6 illustrates only four 2T DRAM cells in a 2T DRAM cell array including a plurality of 2T DRAM cells. Referring to FIG. 6, a standby voltage of the read word line RWL and the read bit line RBL for the write operation and the read operation is the ground voltage GND. Before the read operation, when “H” is written to the cell, the storage node voltage is V_{SN(H)}, and when “L” is stored, the storage node voltage is V_{SN(L)}. In the write operation, the charge corresponding to the storage node voltage V_{SN} is stored in the storage node SN of the cell so as to satisfy the condition of the following Mathematical Expression 5.

$${V}_{SN ( L )} < {V}_{TH} - ∝ \cdot {V}_{DD} < {V}_{SN ( H )} < {V}_{TH} \qquad [ Mathematical Expression 5 ]$$

During the read operation, GND is maintained as is in the read word line RWL of the unselected DRAM cell (two cells on the upper portion), and the first voltage V_{DD} is applied only to the read word line RWL of the selected DRAM cell (two cells on the lower portion). Referring to the above Mathematical Expression 5, in two unselected DRAM cells illustrated in the upper portion, since the storage node voltage V_{SN} is lower than the threshold voltage V_{TH} of the read transistor RT in both the “H” or “L” storage states, V_{GS}<V_{TH}, that is, the gate-source voltage V_{GS} of the read transistor RT becomes lower than the threshold voltage V_{TH} of the read transistor RT, so the read transistor RT in the unselected DRAM cell is turned off, and thus, no unwanted current flows.

In the two selected DRAM cells illustrated in the lower portion, when the first voltage VDD is applied to the read word line RWL, the voltage level of the storage node voltage V_{SN} increases by αV_{DD} due to the capacitive coupling to the third parasitic capacitor C_{SN_RWL}. Here, a is indicated in a fourth mathematical expression of Mathematical Expression 4.

In the case of a cell that stores “H” in the storage node SN of the selected DRAM cell, since the gate-source voltage Vs of the read transistor RT satisfies V_{GS}=V_{SN(H)}+αV_{DD}>V_{TH}, the read transistor RT of the selected cell is turned on and the read current (arrow) flows.

In the case of a cell that stores “L” in the storage node SN of the selected DRAM cell, since the gate-source voltage V_{GS} of the read transistor RT satisfies V_{GS}=V_{SN}(L)+αV_{DD}>V_{TH}, if V_{GS}<V_{TH}, so the read transistor RT is turned off and the read current does not flow.

For the read operation suggested in the present disclosure, the DRAM cell according to the present disclosure should be designed with the asymmetric parasitic capacitor (third parasitic capacitor) so as to satisfy the condition of the following Mathematical Expression 6, which is organized for α related to the relationship between three parasitic capacitors.

$$[ {V}_{TH} - {V}_{SN ( H )} ] / {V}_{DD} < ∝ < [ {V}_{TH} - {V}_{SN ( L )} ] / {V}_{DD} \qquad [ Mathematical Expression 6 ]$$

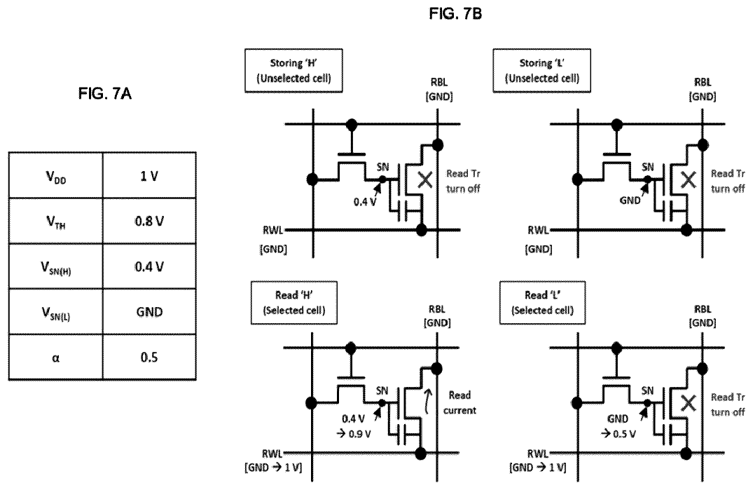

FIGS. 7A and 7B are a diagram illustrating a specific embodiment of the method of driving a 2T DRAM cell with an asymmetric parasitic capacitor according to the present disclosure.

FIG. 7A illustrates a selected cell and an unselected cell among 2T DRAM cells according to the present disclosure, and FIG. 7B illustrates the voltage level at each node when it is assumed that α=0.5.

Referring to FIG. 7B, when performing the read operation of the 2T DRAM cell (hereinafter referred to as a DRAM cell) with the asymmetric parasitic capacitor, if it is assumed that the first voltage V_{DD}, which is the driving voltage of the DRAM cell, is 1 volt (V), the threshold voltage V_{TH} of the read transistor RT is 0.8 V, and the storage node voltage V_{SN}, V_{SN(H)}=0.4 V, V_{SN(L)}=GND, the asymmetric parasitic capacitor of the DRAM cell should satisfy 0.4<α<8 under the condition of [V_{TH}−V_{SN(H)}]/V_{DD}<α<[V_{TH}−V_{SN(L)}]/V_{DD}.

In the embodiment illustrated in FIG. 7A, when a is designed as 0.5, if the information stored in the storage node SN in the read operation for the selected cell is “H”, since V_{GS}=0.9>V_{TH}, the read transistor RT will be turned on and the read current will flow, and if the information stored in the storage node SN is “L”, since V_{GS}=−0.5 V>V_{TH}, the read transistor RT will be turned off and the read current will not flow.

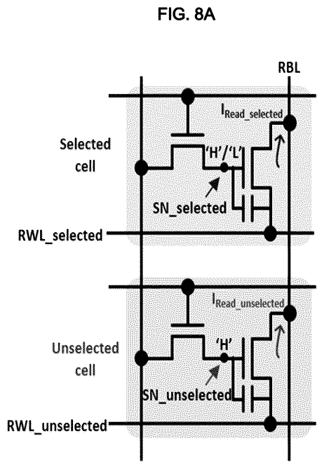

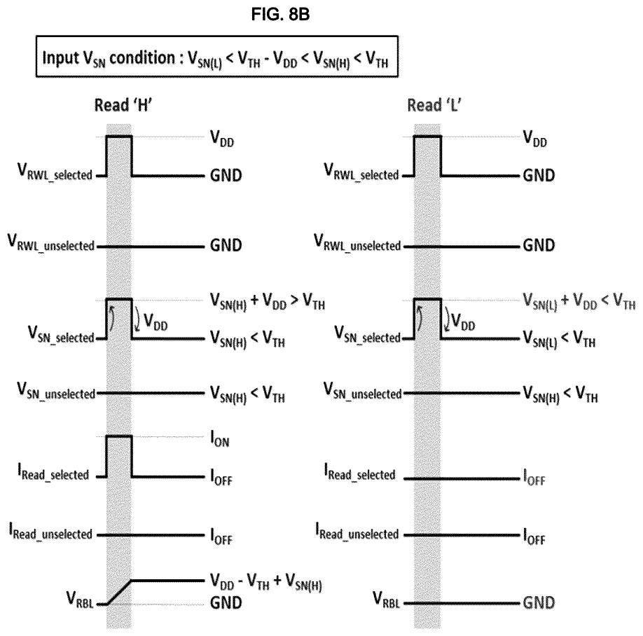

FIGS. 8A and 8B are a diagram illustrating the voltage levels of each node during the read operation of the selected DRAM cell.

FIG. 8A illustrates the selected cell and the unselected cell among the 2T DRAM cells according to the present disclosure, and FIG. 8B illustrates the voltage levels of each node when reading “H” and when reading “L”, respectively.

In FIGS. 8A and 8B, it is assumed that the capacitance of the third parasitic capacitor C_{SN_RWL} is sufficiently larger than the capacitances of the first parasitic capacitor C_{SN_WWL} and the second parasitic capacitor C_{SN_RBL}, so that α=1. In addition, for the description of the worst case, it is assumed that the unselected cell is storing “H”.

Referring to FIGS. 8A and 8B, the read operation is performed by applying a voltage pulse of the first voltage VDD to a read word line RWL selected of the selected cell in the standby state where all read word lines RWL and read bit lines RBL are grounded.

When the selected DRAM cell stores “H” during the read operation (Read “H”), a storage node voltage V_{SN_selected} of the selected DRAM cell increases by the first voltage V_{DD} due to the capacitive coupling, so V_{SN_selected}=V_{SN(H)}+V_{DD}>V_{TH}. Accordingly, the read transistor RT of the selected DRAM cell is turned on, a read current I_{Read_selected} flows, and the voltage level V_{RBL} of the read bit line RBL increases to V_{DD}−V_{TH}+V_{SN(H)}.

During the read operation of the “H” storage information, it is possible to determine that the selected DRAM cell is storing “H” information by sensing a read current I_{Read_selected} that flows or by sensing the increased voltage level V_{RBL} of the read bit line RBL.

During the read operation, even if “H” is stored in the storage node voltage V_{SN_unselected} of the unselected DRAM cell, the ground voltage GND is applied to the read word line RWL unselected of the unselected DRAM cell as it is, so the storage node voltage V_{SN_unselected} of the unselected DRAM cell becomes V_{SN_unselected}=V_{SN(H)}<V_{TH}. As a result, the read transistor RT included in the unselected DRAM cell maintains the turned off state.

Also, since the capacitive coupling by the voltage level V_{RBL} of the read bit line RBL is very small, even if the voltage level V_{RBL} of the read bit line RBL increases while performing the read operation for the “H” information, it does not affect the voltage level of the storage node voltage V_{SN_unselected}.

When the selected DRAM cell stores the “L” information and the read operation is performed (Read “L”), the storage node voltage V_{SN_selected} of the selected DRAM cell increases by the first voltage VDD due to the capacitive coupling, but since the storage node voltage V_{SN_selected} of the selected DRAM cell is V_{SN_selected}=V_{SN(L)}+V_{DD}<V_{TH}, the read transistor RT of the selected DRAM cell is turned off, so the read current I_{Read_selected} does not flow, and the voltage level V_{RBL} of the read bit line RBL maintains the ground voltage GND.

During the read operation for the “L” information of the selected DRAM cell, it is possible to determine that the selected DRAM cell is storing the “L” information by sensing the non-flowing read current I_{Read_selected} or sensing the non-increasing voltage level V_{RBL} of the read bit line RBL.

In this process, even if the “H” information is stored in the storage node voltage V_{SN_unselected} of the unselected DRAM cell, contrary to the description in the read operation of the “H” information of the selected DRAM cell, it has already been described that the read transistor RT of the unselected DRAM cell is turned off so that the unwanted current does not flow, and is not affected by the voltage level V_{RBL} of the read bit line RBL.

According to the present disclosure as described above, the 2T DRAM cell with an asymmetric parasitic capacitor and the 2T DRAM cell array have the advantage of being able to block the flow of current that may occur in the unselected 2T DRAM cell during the read operation of the selected 2T DRAM cell by adding the asymmetric parasitic capacitor to the read transistor constituting the 2T DRAM cell.

Effects which can be achieved by the present disclosure are not limited to the above-described effects. That is, other objects that are not described may be obviously understood by those skilled in the art to which the present disclosure pertains from the following description.

In the above description, the technical idea of the present disclosure has been described along with the accompanying drawings, but this is an exemplary description of a preferred embodiment of the present disclosure and does not limit the present disclosure. In addition, it is clear that anyone skilled in the art of the present disclosure can make various modifications and imitations without departing from the scope of the technical idea of the present disclosure.

What is claimed is:

1. A 2T DRAM cell with an asymmetric parasitic capacitor, comprising:
a write transistor having one terminal connected to a write bit line, the other terminal connected to a storage node, and a gate terminal connected to a write word line;
a read transistor having one terminal connected to a read bit line, the other terminal connected to a read word line, and a gate terminal connected to the storage node; and
an asymmetric parasitic capacitor formed between the gate terminal of the read transistor and the other terminal of the read transistor connected to the read word line.

2. The 2T DRAM cell of claim 1, wherein the asymmetric parasitic capacitor corresponds to an overlapping portion between the gate terminal of the read transistor and an active region of the read transistor connected to the read word line.

3. The 2T DRAM cell of claim 2, wherein an overlapping area between the gate terminal of the read transistor constituting the asymmetric parasitic capacitor and an active region of the read transistor connected to the read word line is wider than an overlapping area between the gate terminal of the read transistor and the active region of the read transistor connected to the read bit line.

4. The 2T DRAM cell of claim 1, wherein a capacitance of the asymmetric parasitic capacitor is greater than a sum of a capacitance of a first parasitic capacitor formed between the gate terminal of the write transistor and the storage node and a capacitance of a second parasitic capacitor formed between the gate terminal of the read transistor and the storage node.

5. A 2T DRAM cell array, comprising:
the plurality of 2T DRAM cells of claim 1, each of which is connected to a write word line, a write bit line, a read word line, and a read bit line,
wherein when a read operation is performed on information stored in a selected 2T DRAM cell among the plurality of 2T DRAM cells,
a read transistor of an unselected 2T DRAM cell among the plurality of 2T DRAM cells is always turned off by the asymmetric parasitic capacitor included in the 2T DRAM cell.

6. The 2T DRAM cell array of claim 5, wherein in the selected 2T DRAM cell, a capacitance of the asymmetric parasitic capacitor is set to a value such that a voltage fluctuation rate of the storage node and a voltage fluctuation rate of the read word line have the same value.

7. The 2T DRAM cell array of claim 5, wherein a magnitude of a capacitance of the asymmetric parasitic capacitor is at least 1000 times larger than a sum of a capacitance of a first parasitic capacitor formed between the gate terminal of the write transistor and the storage node and a capacitance of a second parasitic capacitor formed between the gate terminal of the read transistor and the storage node.

8. The 2T DRAM cell array of claim 5, wherein in the unselected 2T DRAM cell, a voltage value fluctuation rate of the storage node is 0 (zero).

9. The 2T DRAM cell array of claim 5, wherein a threshold voltage V_{TH} of the read transistor, a voltage V_{SN(H)} corresponding to a logic high stored in the storage node, a voltage V_{SH(L)} corresponding to a logic low stored in the storage node, and a voltage VDD applied to a read word line connected to a selected 2T DRAM cell when performing a read operation on information stored in the selected 2T DRAM cell satisfy the following Mathematical Formulas: V_{SN(L)}<V_{TH}−∞·V_{DD}<V_{SN(H)}<V_{TH}, and [V_{TH}−V_{SN(H)}]/V_{DD}<∞<[V_{TH}−V_{SN(L)}]/V_{DD}.

10. The 2T DRAM cell of claim 1, wherein the asymmetric parasitic capacitor having a capacitance value proportional to the area of the overlapping portion between the storage node and the active region of the read transistor.

11. The 2T DRAM cell array of claim 1, comprising:
an asymmetric parasitic capacitor formed by the storage node and the active region of the read transistor, which are formed in separate layers.

12. The 2T DRAM cell array of claim 1, wherein the insulating layer between the storage node and the active region of the read transistor formed on the same layer as the insulating layer between the gate of the read transistor and the channel of the read transistor.

13. The 2T DRAM cell array of claim 1, wherein the insulating layer between the storage node and the active region of the read transistor formed of the same material as the insulating layer between the gate of the read transistor and the channel of the read transistor.
